(19) United States
(12) Patent Application Publication
(10) Pub. No.: US 2025/0125787 A1
(43) Pub. Date: Apr. 17, 2025

(54) SURFACE ACOUSTIC WAVE FILTER WITH CONNECTED BAR PISTONS

(71) Applicant: WISOL CO., LTD., Osan-si (KR)

(72) Inventors: Hun Yong LEE, Osan-si (KR); Yoshikazu KIHARA, Osan-si (KR)

(21) Appl. No.: 18/894,136

(22) Filed: Sep. 24, 2024

(30) Foreign Application Priority Data
Oct. 17, 2023 (KR) 10- 2023-0138412

(51) Int. Cl. H03H 9/64; H03H 3/08; H03H 9/02

(52) U.S. Cl. CPC H03H 9/64; H03H 3/08; H03H 9/02992

(57) ABSTRACT

The present invention relates to a surface acoustic wave filter with connected bar pistons, the filter comprising: on a substrate where a support substrate, an energy confinement layer, and a piezoelectric layer are sequentially laminated, an IDT electrode unit including a first bus bar and a second bus bar extended in a first direction and spaced apart from each other in a second direction perpendicular to the first direction, and a plurality of first IDT electrodes and a plurality of second IDT electrodes alternately extended from the first bus bar and the second bus bar in the second direction, and spaced apart from each other in the first direction; and lower and upper bar pistons formed in a shape of a strip extended in the first direction to cover tips of the plurality of first IDT electrodes and the plurality of second IDT electrodes, wherein the upper bar piston and the lower bar piston are connected by bar piston connection units in an area excluding the IDT electrode unit.

### BACKGROUND OF THE INVENTION

### Field of the Invention

The present invention relates to a surface acoustic wave filter with connected bar pistons, and more specifically, to a surface acoustic wave filter, which improves productivity and defect rate by forming disconnected bar pistons to be connected to each other, in order to prevent defects occurring in the process of manufacturing bar pistons formed to suppress spurious components generated by transverse mode.

### Background of the Related Art

A Surface Acoustic Wave (SAW) refers to a wave that propagates along the surface of an elastic solid, and the surface acoustic wave propagates with energy concentrated near the surface and corresponds to a mechanical wave. The surface acoustic wave device is an electromechanical device that utilizes interactions between the surface acoustic waves and semiconductor conduction electrons, and uses surface acoustic waves transferred to the surface of a piezoelectric crystal. The surface acoustic wave device may have a very wide range of industrial applications including sensors, oscillators, filters, and the like, and may be miniaturized and lightweighted to have various advantages such as robustness, stability, sensitivity, low cost, real-time property, and the like.

However, spurious components may be generated by unnecessary transverse modes of a surface acoustic wave filter, and as insertion loss increases, performance may be adversely affected. In order to reduce the side effects generated by the transverse modes, a method of reducing the propagation speed of surface acoustic waves by forming an edge unit having a low acoustic velocity in the IDT electrode has been proposed.

The applicant of the present invention has also developed a surface acoustic wave resonator that implements the edge unit as a low acoustic velocity region. The surface acoustic wave filter may be formed to have one or more surface acoustic wave resonators. A single-band surface acoustic wave filter may be formed by configuring a single surface acoustic wave resonator, and a multi-band surface acoustic wave filter may be formed by connecting a plurality of surface acoustic wave resonators in parallel.

FIG. 1 is a view showing a surface acoustic wave resonator having a dot-shape mass-added film formed thereon, and FIG. 2 is a cross-sectional view showing section AA′ of the surface acoustic wave resonator according to FIG. 1.

Referring to FIGS. 1 and 2, a first bus bar 120 and a second bus bar 125 extended in a first direction and spaced apart from each other in a second direction perpendicular to the first direction are formed on a substrate 100 on which a support substrate, an energy confinement layer, and a piezoelectric layer are sequentially laminated.

Next, a plurality of first IDT electrodes 130 and second IDT electrodes 135 are formed to be alternately extended from the first bus bar 120 and the second bus bar 125 in the second direction and spaced apart from each other in the first direction.

On the substrate 100, a pair of reflectors 180A and 180B are provided on both sides of the first IDT electrodes 130 or the second IDT electrodes 135 in the first direction. The first IDT electrodes 130, the second IDT electrodes 135, and the reflectors 180A and 180B may be formed as a metal film.

Within an area where the first IDT electrode 130 and the second IDT electrode 135 overlap, edge units having an acoustic velocity lower than that of the center portion are formed at both ends of the center portion.

Referring to the markings of regions on the left side of FIG. 1, the region corresponding to C2 or C3 represents the edge unit, the region corresponding to C1 represents the center portion, and the acoustic velocity of the region corresponding to C2 or C3 is formed to be lower than the acoustic velocity of region C1.

Referring to FIGS. 1 and 2, in order to implement the region of C2 or C3 as a low acoustic velocity region, a dot-shape mass-added film 160 is formed on the top surface of the region of C2 or C3 of the IDT electrode.

As the dot-shape mass-added film 160 is added on the edge unit C2 and C3, the acoustic velocity in the edge unit C2 and C3 is decreased to be lower than the acoustic velocity in the center portion C1 of the IDT electrode.

However, when the mass-added film 160 is formed by adding a dot-shape electrode in this way, the width of the dot-shape mass-added film 160 should be equal to or smaller than the width of the IDT electrodes 130 and 135 since short circuit between the IDT electrodes 130 and 135 should be avoided. In addition, considering the overlapping error of the photo process, the design dimensions should be implemented further smaller.

For example, since the width of a typical IDT electrode of a surface acoustic wave resonator of 2 GHz band is 0.5 μm or lower, the width of the dot-shape electrode should be implemented to be 0.4 μm or lower. Since the width of the dot-shape mass-added film 160 is the smallest among the elements constituting the surface acoustic wave resonator 110, the process of forming the dot-shape mass-added film 160 with a width smaller than the width of the IDT electrodes 130 and 135 by securing tightness without misalignment with the IDT electrodes 130 and 135 is the most difficult process in manufacturing a surface acoustic wave filter.

When the dot-shape mass-added film 160 is misaligned left and right due to a deviation in the manufacturing process and gets out of the IDT electrodes 130 and 135, a performance defect may occur in the surface acoustic wave filter as the desired function of suppressing spurious components may not be properly performed.

To overcome these shortcomings, the applicant has developed a method of implementing a low acoustic velocity mode by forming bar pistons of a long strip-shape dielectric material as shown in FIG. 3, rather than a dot-shape dielectric material, in the edge region.

FIG. 3 is a view showing a surface acoustic wave resonator having bar pistons formed in this way, FIG. 4 is a cross-sectional view showing section AA′ of the surface acoustic wave resonator according to FIG. 3, and FIG. 5 is a cross-sectional view showing section BB′ of the surface acoustic wave resonator according to FIG. 3.

Referring to FIGS. 3 to 5, the first bus bar 120 and the second bus bar 125, the first IDT electrode 130 and the second IDT electrode 135, and the reflectors 180A and 180B included in the surface acoustic wave resonator 110 are formed in the same manner as described in the surface acoustic wave resonator 110 including the dot-shape mass-added film 160.

Within an area where the first IDT electrode 130 and the second IDT electrode 135 overlap, edge units having an acoustic velocity lower than that of the center portion are formed at both ends of the center portion.

Referring to the markings of regions on the left side of FIG. 3, the region corresponding to C2 or C3 represents the edge unit, the region corresponding to C1 represents the center portion, and the acoustic velocity of the region corresponding to C2 or C3 is formed to be lower than the acoustic velocity of region C1.

Referring to FIGS. 3 to 5, in order to implement the region of C2 or C3 as a low acoustic velocity region, the bar piston 162 may be integrally formed to be extended across plurality of first IDT electrodes 130 and second IDT electrodes 135. The bar piston 162 may cross the plurality of IDT electrodes 130 and 135 and completely fill the regions between the plurality of electrodes to have a shape of single strip. Since the piston mode is implemented using a dielectric material of a bar shape in this way, it is referred to as a bar piston 162.

As the bar piston 162 is added on the edge units C2 and C3, the acoustic velocity in the edge units C2 and C3 is decreased to be lower than the acoustic velocity in the center portion C1 of the IDT electrode.

Since the material of the strip-shape bar piston 162 is a dielectric material, it is not worried that the IDT electrodes 130 and 135 will be short-circuited with each other. In addition, since the strip shape is continuously formed in the first direction, it does not need to consider an overlapping error in the first direction in the photo process.

FIG. 6 is a plan view showing a substrate of a surface elastic wave filter having bar pistons in this way, in which (a) shows a substrate formed by arranging a plurality of surface acoustic wave resonators, and (b) shows a photoresist mask for forming bar pistons on the substrate.

The thickness of a typical bar piston 162 is about 0.55 λ when the period of the IDT electrode is λ. In the case of a SAW filter having a resonant frequency of 2 GHZ, the period λ is about 1.5 μm, and at this point, the thickness of the bar piston is about 0.8 μm. In FIG. 6, the thickness of the bar piston 162 is shown enlarged for explanation.

A lift-off process is used to form the strip-shape bar piston 162. FIG. 7 is a view showing the lift-off process, and describes the process of forming the bar piston 162 with reference to FIG. 7.

First, referring to FIG. 7(a), a photoresist 190 is coated on the substrate 100 on which IDT electrodes 130 and 135 are formed. The photoresist 190 is removed through a masking and exposure process so that the dielectric material 164 may be deposited only on the bar piston 162 area.

Next, referring to FIG. 7(b), the dielectric material 164 to be formed as the bar piston 162 is deposited on the entire surface of the substrate 100.

Then, referring to FIG. 7(c), when the substrate 100 is immersed in a resist stripping solution 191 to peel off the photoresist 190 from the substrate 100, the photoresist 190 may be removed as the resist stripping solution 191 penetrates into the gap between the photoresist 190 and the dielectric material 164.

When the photoresist 190 is completely removed, a dielectric pattern having a shape as shown in FIG. 7(d) is formed on the IDT electrodes 130 and 135.

However, it is not easy to form the narrow and long strip-shape bar pistons separated like islands as shown in FIG. 6(b) using the lift-off process. This is since that a narrow area of the strip shape should be left to be formed as the bar piston 162, and a large area of the photoresist 190 around the bar piston 162 should be peeled off.

In addition, when the photoresist 190 is peeled off, the IDT electrodes 130 and 135 of the surface acoustic wave resonator 110 are damaged in some cases as the photoresist is removed in very large lumps, and accordingly, performance of the surface acoustic wave filter can be degraded.

As described above, it needs to eliminate the difficulties of the lift-off process performed to form the bar pistons and the defects generated in the process.

### SUMMARY OF THE INVENTION

Therefore, the present invention has been made in view of the problems, and it is an object of the present invention to provide a surface acoustic wave filter, which can prevent the damage to IDR electrodes occurring in the process of forming bar pistons added to suppress spurious components generated by transverse mode.

The technical problems of the present invention are not limited to the technical problems mentioned above, and unmentioned other technical problems will be clearly understood by those skilled in the art from the following description.

To accomplish the object, according to one aspect of the present invention, there is provided a surface acoustic wave filter with connected bar pistons, the filter comprising: on a substrate where a support substrate, an energy confinement layer, and a piezoelectric layer are sequentially laminated, an IDT electrode unit including a first bus bar and a second bus bar extended in a first direction and spaced apart from each other in a second direction perpendicular to the first direction, and a plurality of first IDT electrodes and a plurality of second IDT electrodes alternately extended from the first bus bar and the second bus bar in the second direction, and spaced apart from each other in the first direction; and lower and upper bar pistons formed in a shape of a strip extended in the first direction to cover tips of the plurality of first IDT electrodes and the plurality of second IDT electrodes, wherein the upper bar piston and the lower bar piston are connected by bar piston connection units in an area excluding the IDT electrode unit.

In some embodiments of the present invention, the SAW filter may further comprise reflectors formed on both sides of the IDT electrode unit in the first direction.

In some embodiments of the present invention, the bar piston connection units are formed outside the reflectors.

In some embodiments of the present invention, the bar piston connection units are formed across outside and inside of the reflectors.

In some embodiments of the present invention, the bar piston connection units include a disconnected section.

In some embodiments of the present invention, the bar piston connection units include a curved section.

In some embodiments of the present invention, thickness of the bar piston connection units is non-uniform.

To accomplish the object, according to one aspect of the present invention, there is provided a method of manufacturing a surface acoustic wave filter, the method comprising the steps of: forming, on a substrate where a support substrate, an energy confinement layer, and a piezoelectric layer are sequentially laminated, an IDT electrode unit including a first bus bar and a second bus bar extended in a first direction and spaced apart from each other in a second direction perpendicular to the first direction, and a plurality of first IDT electrodes and a plurality of second IDT electrodes alternately extended from the first bus bar and the second bus bar in the second direction, and spaced apart from each other in the first direction; and forming lower and upper bar pistons in a shape of a strip extended in the first direction to cover tips of the plurality of first IDT electrodes and the plurality of second IDT electrodes, wherein the upper bar piston and the lower bar piston are connected by bar piston connection units in an area excluding the IDT electrode unit.

To accomplish the object, according to one aspect of the present invention, there is provided a method of manufacturing a surface acoustic wave filter, the method comprising the steps of: simultaneously forming, on a substrate where a support substrate, an energy confinement layer, and a piezoelectric layer are sequentially laminated, a plurality of surface acoustic wave resonators comprising an IDT electrode unit including a first bus bar and a second bus bar extended in a first direction and spaced apart from each other in a second direction perpendicular to the first direction, and a plurality of first IDT electrodes and a plurality of second IDT electrodes alternately extended from the first bus bar and the second bus bar in the second direction, and spaced apart from each other in the first direction; and forming lower and upper bar pistons in a shape of a strip extended in the first direction to cover tips of the plurality of first IDT electrodes and the plurality of second IDT electrodes, wherein the plurality of surface acoustic wave resonators is connected in parallel, and the bar pistons are connected by bar piston connection units in an area excluding the IDT electrode unit.

In some embodiments of the present invention, the bar piston connection units are formed to be extended to an outer edge of the surface acoustic wave resonators.

In some embodiments of the present invention, the bar piston connection units are formed by connecting the surface acoustic wave resonators.

In some embodiments of the present invention, the bar piston connection unit is formed to be extended to an outer edge of the substrate.

The surface acoustic wave filter with connected bar pistons according to the present invention may quickly and easily perform a lift-off process for forming bar pistons by additionally forming and connecting the bar pistons in an area excluding the IDT electrode unit, and in particular, may prevent damage that may occur in the IDT electrodes by making the lumps to be peeled off small. In this way, when manufacturing a surface elastic wave filter, productivity can be improved by increasing the processing speed and preventing occurrence of defects.

### BRIEF DESCRIPTION OF THE DRAWINGS

FIG. 1 is a view showing a surface acoustic wave resonator having a dot-shape mass-added film formed thereon.

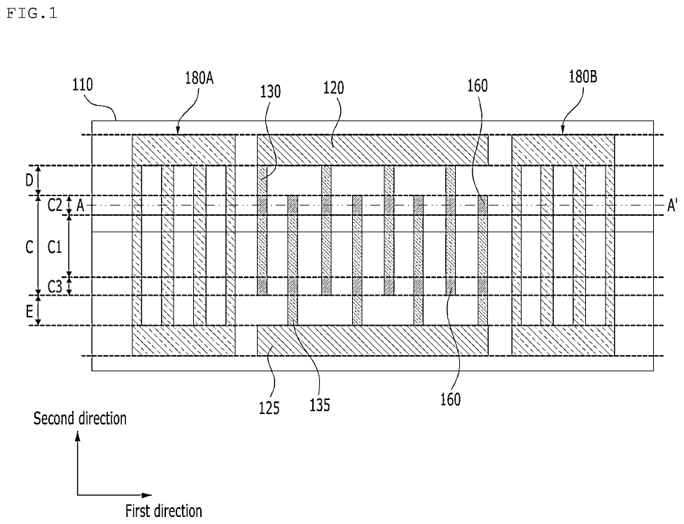

FIG. 2 is a cross-sectional view showing section AA′ of the surface acoustic wave resonator according to FIG. 1.

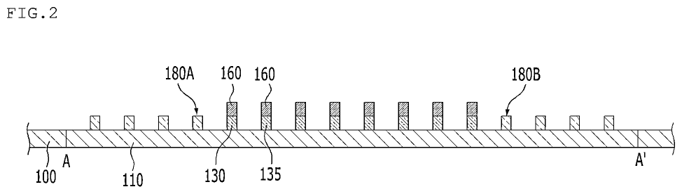

FIG. 3 is a view showing a surface acoustic wave resonator having bar pistons formed thereon.

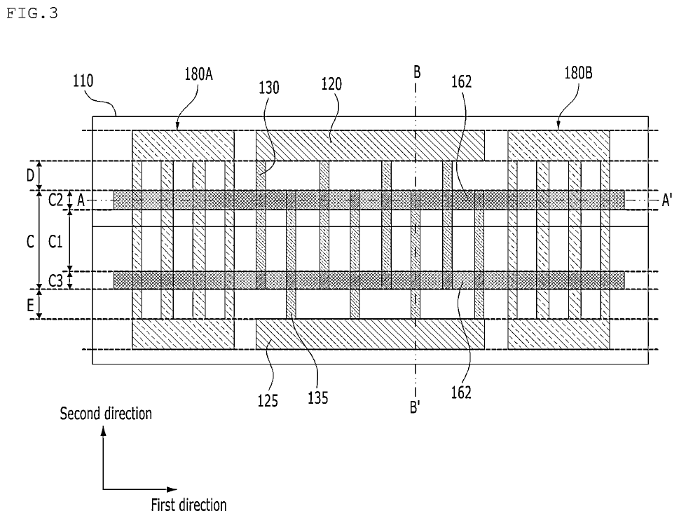

FIG. 4 is a cross-sectional view showing section AA′ of the surface acoustic wave resonator according to FIG. 3.

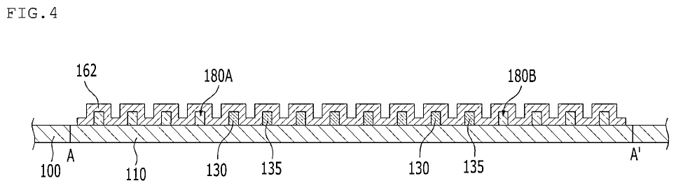

FIG. 5 is a cross-sectional view showing section BB′ of the surface acoustic wave resonator according to FIG. 3.

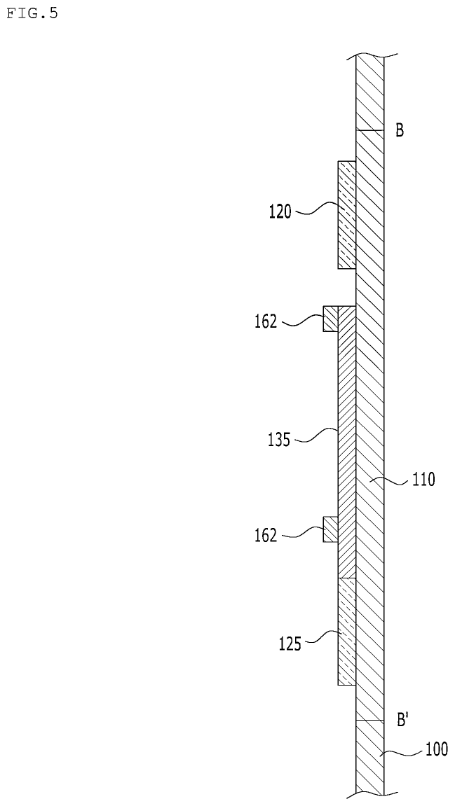

FIG. 6 is a plan view showing a substrate of a surface elastic wave filter having bar pistons.

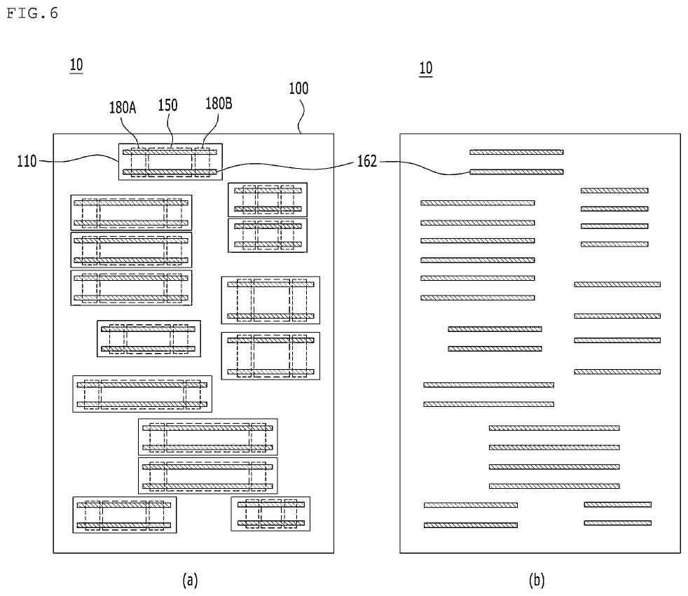

FIG. 7 is a view showing a lift-off process.

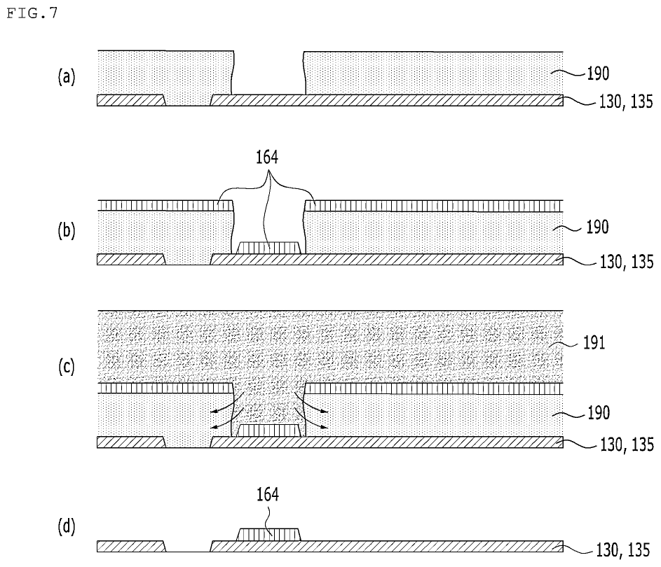

FIG. 8 is a view showing a surface acoustic wave resonator according to an embodiment of the present invention.

FIG. 9 is a plan view showing a substrate of a surface acoustic wave filter according to an embodiment of the present invention.

FIG. 10 is a view showing an example of connecting bar pistons according to an embodiment of the present invention.

FIG. 11 is a plan view showing a substrate including connection of bar pistons in a surface acoustic wave filter according to an embodiment of the present invention.

FIG. 12 is a view showing connection of bar pistons in adjacent surface acoustic wave filters according to an embodiment of the present invention.

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

In addition, throughout the specification, when a part is said to be “connected” to another part, this also includes “indirectly” or “electrically connected” cases with intervention of other members or components therebetween, as well as “directly connected” cases.

In addition, throughout the specification, the description that each layer (film), region, pattern, or structure is formed “above/on” or “beneath/under” a substrate, each layer (film), region, pad, or pattern includes both cases that they are formed directly and formed with intervention of other layers. The criteria for being above/on or beneath/under each layer are explained with reference to the drawings.

In addition, expressions such as ‘first, second’, and the like are only used to distinguish a plurality of components, and do not limit the sequence of the components or other features.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

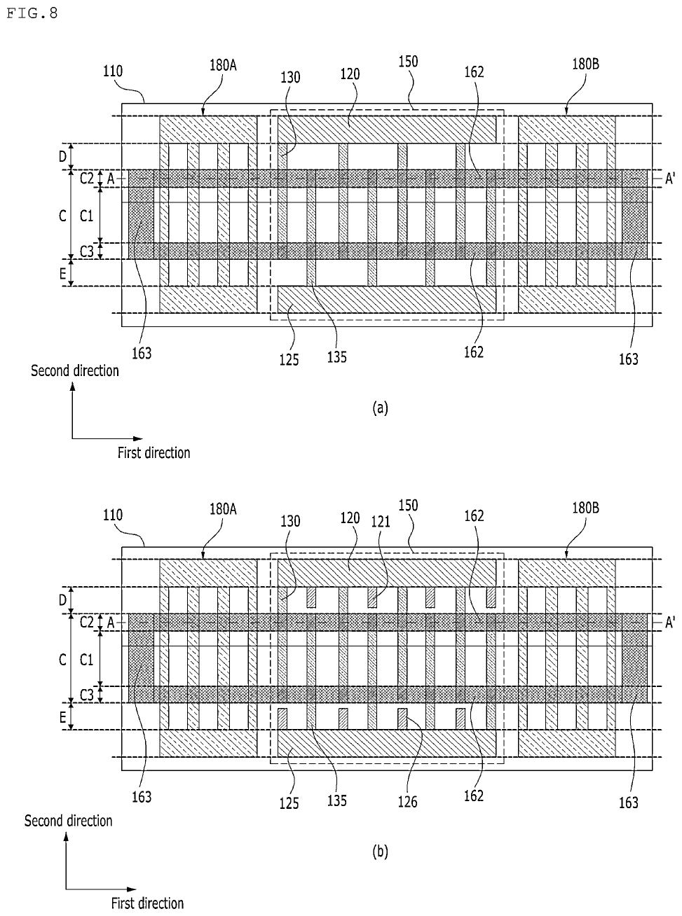

The present invention will be described in detail with reference to the drawings. FIG. 8 is a view showing a surface acoustic wave resonator according to an embodiment of the present invention, in which (a) show a case without a dummy electrode, and (b) show a case with a dummy electrode.

Referring to FIG. 8, a surface acoustic wave resonator 110 according to an embodiment of the present invention may include a substrate 100, a first bus bar 120, a second bus bar 125, a plurality of first IDT electrodes 130, a plurality of second IDT electrodes 135, reflectors 180A and 180B, bar pistons 162, and bar piston connection units 163. It may further include dummy electrodes 121 and 126.

The substrate 100 may be a multilayer substrate including a plurality of layers. The plurality of layers may include, for example, a support substrate including silicon, a high acoustic velocity film including a material such as amorphous silicon (a-Si) or polysilicon, a low acoustic velocity film including silicon oxide (SiO₂), and a piezoelectric layer including a material such as LiTaO₃ (LT) or LiNbO₃ (LN) located on top of the low acoustic velocity film, i.e., at the uppermost portion.

A first bus bar 120 and a second bus bar 125 extended in a first direction and spaced apart from each other in a second direction perpendicular to the first direction are formed on the substrate 100. The bus bars 120 and 125 may contain a conductive material.

A plurality of first IDT electrodes 130 and second IDT electrodes 135 alternately extended from the first bus bar 120 and the second bus bar 125 in the second direction and spaced apart from each other in the first direction are formed.

The first IDT electrode 130 may be formed to be integrated with the first bus bar 120, and the second IDT electrode 135 may be formed to be integrated with the second bus bar 125.

The region including the first bus bar 120 and the second bus bar 125 and the first IDT electrode 130 and the second IDT electrode 135 is defined as an IDT electrode unit 150.

In addition, on the substrate 100, a pair of reflectors 180A and 180B may be formed on both sides of the IDT electrode unit 150 in the first direction. That is, the pair of reflectors 180A and 180B are arranged to insert the IDT electrode unit 150 therebetween. One reflector 180A may be formed to be adjacent to the left side of the IDT electrode unit 150, and the other reflector 180B may be formed to be adjacent to the right side of the IDT electrode unit 150.

The IDT electrodes 130 and 135 and the reflectors 180A and 180B may be formed as a single-layer metal film or a laminated metal film. The IDT electrodes 130 and 135 and the reflectors 180A and 180B may be simultaneously formed in the same process as the bus bars 120 and 125, for example, a deposition process.

Within the area where the first IDT electrode 130 and the second IDT electrode 135 overlap, edge units having an acoustic velocity lower than that of the center portion may be formed at both ends of the center portion.

Referring to the markings of regions on the left side of FIG. 8, the region corresponding to C2 or C3 represents the edge unit, the region corresponding to C1 represents the center portion, and the acoustic velocity of the region corresponding to C2 or C3 may be formed to be lower than the acoustic velocity of region C1.

Referring to FIG. 8, in order to implement the region of C2 or C3 as a low acoustic velocity region, the bar piston 162 may be integrally formed to be extended across a plurality of IDT electrodes 130 and 135. That is, the bar piston 162 may cross the plurality of IDT electrodes 130 and 135 and completely fill the regions between the plurality of electrodes to have a shape of single strip. When the bar piston 162 is added to the edge units C2 and C3, the acoustic velocity in the edge units C2 and C3 is decreased to be lower than that of the center portion C1 of the IDT electrode.

In this way, a bar piston 162 covering the tips of the first IDT electrodes 130 and a bar piston 162 covering the tips of the second IDT electrodes 135 may be formed in two places. At this point, the bar piston 162 covering the tips of the first IDT electrodes 130 is referred to as a lower bar piston 162, and the bar piston 162 covering the tips of the second IDT electrodes 135 is referred to as an upper bar piston 162.

Particularly, in the surface acoustic wave resonator 110 according to an embodiment of the present invention, the upper and lower bar pistons 162 may be connected by bar piston connection units 163 in the area excluding the IDT electrode unit 150.

The bar pistons 162 and the bar piston connection units 163 may be formed simultaneously and include an insulator.

At this point, the bar pistons 162 and the bar piston connection units 163 may have a density of 5 g/cm³ or lower and contain at least one among SiO₂, Ta₂O₅, and Al₂O₃ as a material.

Meanwhile, although it is shown in FIG. 8 that the bar piston connection units 163 are located on the outer side and 180B, the bar piston surfaces of the reflectors 180A connection units 163 may be formed on the outer lateral sides of the IDT electrode unit 150. The bar piston connection units 163 may also be formed between the reflectors 180A and 180B and the IDT electrode unit 150.

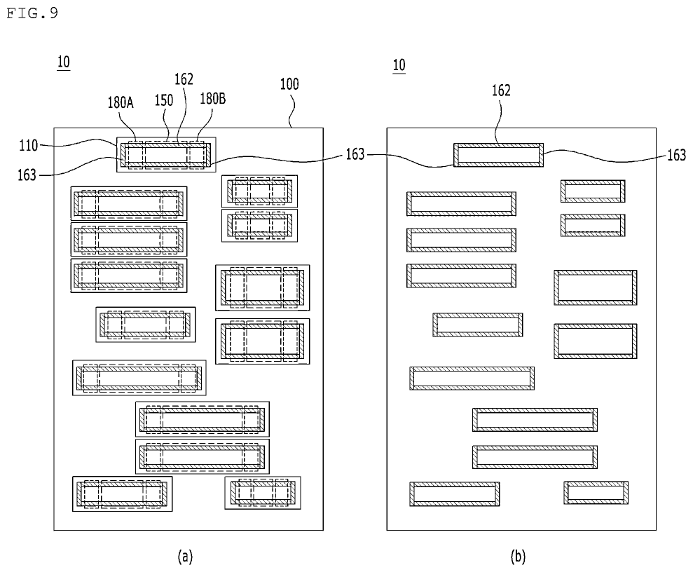

FIG. 9 is a plan view showing a substrate of a surface acoustic wave filter according to an embodiment of the present invention, in which (a) shows a substrate formed by arranging a plurality of surface acoustic wave resonators, and (b) shows a photoresist mask for forming the bar pistons and the bar piston connection units on the substrate. The surface acoustic wave filter 10 may be formed to have one or more surface acoustic wave resonators 110. A single-band surface acoustic wave filter 10 may be formed by configuring a single surface acoustic wave resonator 110, and a multi-band surface acoustic wave filter 10 may be formed by connecting a plurality of surface acoustic wave resonators 110 in parallel.

Referring to FIG. 9(a), a plurality of surface acoustic wave resonators 110 formed on the substrate 100 may be connected in parallel to be completed as the surface acoustic wave filter 10.

Referring to FIGS. 8 and 9, the upper and lower bar pistons 162 may be connected by the bar piston connection units 163 to be formed in a closed shape.

When the upper and lower bar pistons 162 and the bar piston connection units 163 are connected and formed in this way, since the resist stripping solution 191 may further penetrate into the gap between the photoresist 190 and the dielectric material 164 and peel off the photoresist in small lumps in the lift-off process, the peeled off lumps may be prevented from damaging the IDT electrodes.

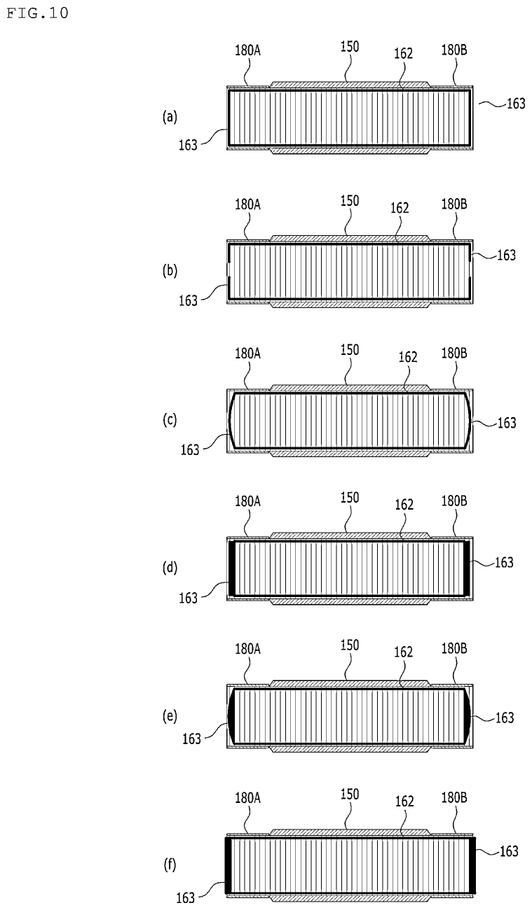

FIG. 10 is a view showing various examples of connecting bar pistons according to an embodiment of the present invention.

Referring to FIG. 10(a), the upper and lower bar pistons 162 may be connected by the bar piston connection units 163 having the same thickness as the bar pistons 162 of the IDT electrode unit 150 in the areas of the reflectors 180A and 180B.

Referring to FIG. 10(b), although the upper and lower bar pistons 162 are connected by the bar piston connection units 163 having the same thickness as the bar pistons 162 of the IDT electrode unit 150 in the areas of the reflectors 180A and 180B, a disconnected section may be included in the middle.

Referring to FIG. 10(c), the upper and lower bar pistons 162 may be connected by curved bar piston connection units 163 having the same thickness as the bar pistons 162 of the IDT electrode unit 150 in the areas of the reflectors 180A and 180B. In particular, in order to evenly distribute the resist stripping solution 191 without being concentrated, it is desirable to avoid an acute angle in the shape of the connection units and process it as a curved line.

Referring to FIG. 10(d), the upper and lower bar pistons 162 may be connected by the bar piston connection units 163 having a thickness thicker than the bar pistons 162 of the IDT electrode unit 150 in the areas of the reflectors 180A and 180B. It may be advantageous to form the bar piston connection units 163 as thick as possible within the range of area that can be secured within the surface acoustic wave resonator 110 to penetrate the resist stripping solution 191 more quickly and deeply.

Referring to FIG. 10(e), the upper and lower bar pistons 162 may be connected by the bar piston connection units 163 of non-uniform thickness in the areas of the reflectors 180A and 180B.

Referring to FIG. 10(f), the upper and lower bar pistons 162 may be connected by the bar piston connection units 163 provided in both the outer and inner areas of the reflectors 180A and 180B.

In all cases of FIG. 10(a) to (f), it can be confirmed that the surface acoustic wave resonator 110 according to the present invention maintains the performance of suppressing spurious components. Therefore, design optimization can be achieved by combining cases (a) to (f) according to the design conditions of each surface acoustic wave resonator 110.

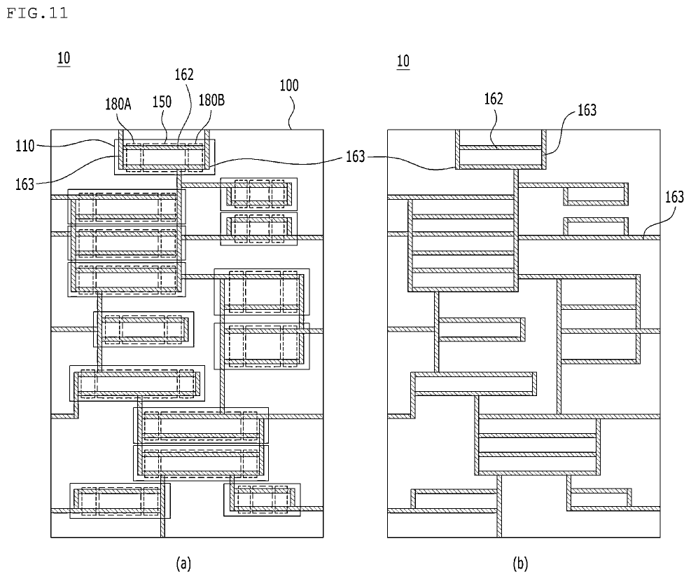

FIG. 11 is a plan view showing a substrate including connection of bar pistons in a surface acoustic wave filter according to an embodiment of the present invention, in which (a) shows a substrate formed by arranging a plurality of surface acoustic wave resonators, and (b) shows a photoresist mask for forming bar pistons and the bar piston connection units on the substrate.

Referring to FIG. 11, the surface acoustic wave resonator 110 may be connected to another surface acoustic wave resonator 110 arranged on the substrate 100 by the bar piston connection units 163. At this point, the bar piston connection units 163 additionally formed for connection should not invade the area of the IDT electrode unit 150 of the surface acoustic wave resonator 110. In addition, the bar piston connection units 163 formed outside the surface acoustic wave resonator 110 may be formed to be extended to the outer edge of the substrate 100. In addition, in order for the bar piston connection units 163 to connect the surface acoustic wave resonators 110 to each other as described above, the bar piston connection units 163 may be formed to be extended from the inside to the outer edge of the surface acoustic wave resonator 110.

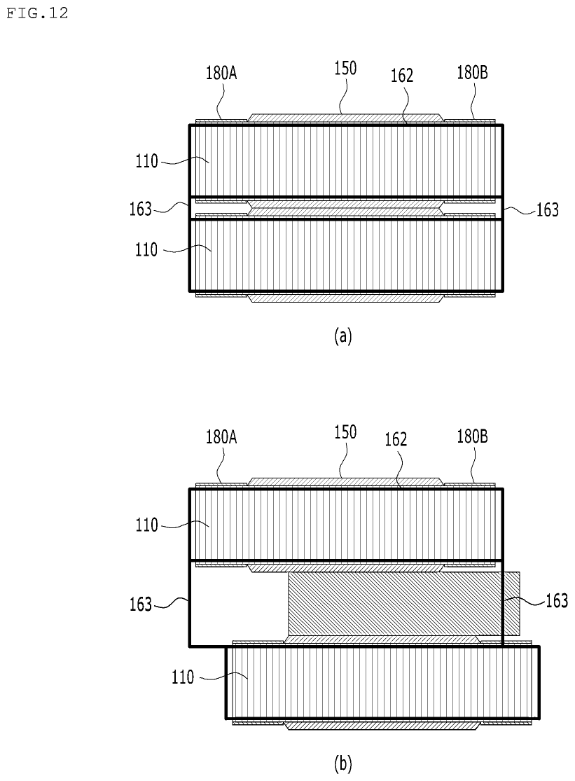

FIG. 12 is a view showing an example of connecting bar pistons in adjacent surface acoustic wave filters according to an embodiment of the present invention.

FIG. 12(a) shows a case where two surface acoustic wave resonators are arranged up and down to be in contact. The surface acoustic wave resonators arranged up and down may be directly connected by the bar piston connection units 163 shaped in a straight line.

FIG. 12(b) shows a case where two surface acoustic wave resonators are arranged up and down to be misaligned with each other. The surface acoustic wave resonators arranged up and down may be connected by the bar piston connection units 163 shaped in a straight line or a right-angled form avoiding the IDT electrode unit 150.

When the bar piston connection units 163 are formed to connect different surface acoustic wave resonators 110 arranged on the same substrate 100 to each other or to be extended to the outer edge of the substrate 100 in this way, the area of the bar piston connection units 163 increases, and the area to be peeled off in the lift-off process decreases, and the resist stripping solution 191 may further penetrate during the peeling, so that it is more advantageous for preventing defects that occur when peeling the photoresist 190 off. Since the resist stripping solution 191 may quickly and sufficiently penetrate into the gap between the photoresist 190 and the dielectric material 164 and peel off in a large number of small lumps during the peeling, the chances of damaging the IDT electrodes 130 and 135 by the peeled off lumps can be further reduced when the photoresist 190 is peeled off.

The surface acoustic wave resonators 110 may be connected in parallel to complete the surface acoustic wave filter 10 having multiple bands.

Although adjacent surface acoustic wave resonators 110 are connected to each other by the bar piston connection units 163 of various shapes, performance of suppressing the spurious components of the surface acoustic wave resonators 110 is maintained. Although the connection shape includes a disconnected section or is formed at a non-uniform thickness, degradation in performance does not occur. Therefore, design optimization can be achieved by connecting the bar pistons 162 in various shapes according to the design conditions of each surface acoustic wave resonator 110.

In addition, it is desirable to process the shape of the connection units as a curved line so that the resist stripping solution 191 may be evenly distributed without being concentrated.

Although the present invention has been described as described above, those skilled in the art will recognize that the present invention may be implemented in other forms while maintaining the technical ideas and essential features of the present invention.

Although the scope of right of the present invention will be determined basically by the patent claims, it should be interpreted that all changes or modified forms derived from equivalent configurations, as well as the configurations directly derived from the description of the patent claims, are included in the scope of right of the present invention.

### DESCRIPTION OF SYMBOLS

10: Surface acoustic wave filter
100: Substrate
110: Surface acoustic wave resonator
120: First bus bar
121: First dummy electrode
125: Second bus bar
126: Second dummy electrode
130: First IDT electrode
135: Second IDT electrode
150: IDT electrode unit
160: Mass-added film
162: Bar piston
163: Bar piston connection unit
164: Dielectric material
180A, 180B: Reflector
190: Photoresist
191: Resist stripping solution

What is claimed is:

1. A surface acoustic wave filter with connected bar pistons, the filter comprising:
on a substrate where a support substrate, an energy confinement layer, and a piezoelectric layer are sequentially laminated,
an IDT electrode unit including a first bus bar and a second bus bar extended in a first direction and spaced apart from each other in a second direction perpendicular to the first direction, and a plurality of first IDT electrodes and a plurality of second IDT electrodes alternately extended from the first bus bar and the second bus bar in the second direction, and spaced apart from each other in the first direction; and
lower and upper bar pistons formed in a shape of a strip extended in the first direction to cover tips of the plurality of first IDT electrodes and the plurality of second IDT electrodes, wherein
the upper bar piston and the lower bar piston are connected by bar piston connection units in an area excluding the IDT electrode unit.

2. The SAW filter according to claim 1, further comprising reflectors formed on both sides of the IDT electrode unit in the first direction.

3. The SAW filter according to claim 2, wherein the bar piston connection units are formed outside the reflectors.

4. The SAW filter according to claim 2, wherein the bar piston connection units are formed across outside and inside of the reflectors.

5. The SAW filter according to claim 1, wherein the bar piston connection units include a disconnected section.

6. The SAW filter according to claim 1, wherein the bar piston connection units include a curved section.

7. The SAW filter according to claim 1, wherein thickness of the bar piston connection units is non-uniform.

8. A method of manufacturing a surface acoustic wave filter, the method comprising the steps of:
forming, on a substrate where a support substrate, an energy confinement layer, and a piezoelectric layer are sequentially laminated, a surface acoustic wave resonator comprising an IDT electrode unit including a first bus bar and a second bus bar extended in a first direction and spaced apart from each other in a second direction perpendicular to the first direction, and a plurality of first IDT electrodes and a plurality of second IDT electrodes alternately extended from the first bus bar and the second bus bar in the second direction, and spaced apart from each other in the first direction; and
forming lower and upper bar pistons in a shape of a strip extended in the first direction to cover tips of the plurality of first IDT electrodes and the plurality of second IDT electrodes,
wherein the upper bar piston and the lower bar piston are connected by bar piston connection units in an area excluding the IDT electrode unit.

9. The method according to claim 8, wherein the step of forming the surface acoustic wave resonator is characterized to form a plurality of surface acoustic wave resonators, and the plurality of surface acoustic wave resonators is connected in parallel.

10. The method according to claim 8, wherein the SAW filter further includes reflectors formed on both sides of the IDT electrode unit in the first direction.

11. The method according to claim 10, wherein the bar piston connection units are formed outside the reflectors.

12. The method according to claim 10, wherein the bar piston connection units are formed across outside and inside of the reflectors.

13. The method according to claim 9, wherein the bar piston connection units are formed to be extended to an outer edge of the surface acoustic wave resonators.

14. The method according to claim 9, wherein the bar piston connection units are formed by connecting the surface acoustic wave resonators.

15. The method according to claim 9, wherein the bar piston connection unit is formed to be extended to an outer edge of the substrate.

16. The method according to claim 8, wherein the bar piston connection units include a disconnected section.

17. The method according to claim 8, wherein the bar piston connection units include a curved section.

18. The method according to claim 8, wherein thickness of the bar piston connection units is non-uniform.
